(19) United States
(12) Patent Application Publication
(10) Pub. No.: US 2025/0046629 A1
(43) Pub. Date: Feb. 6, 2025

(54) ION BEAM ETCHING APPARATUS, METHOD FOR MANUFACTURING SEMICONDUCTOR DEVICE USING THE SAME, AND METHOD FOR TREATING SUBSTRATE USING THE SAME

(71) Applicant: Samsung Electronics Co., Ltd., Suwon-si (KR)

(72) Inventors: Geun Young YEOM, Seoul (KR); Jin Woo PARK, Suwon-si (KR); Sang Wuk PARK, Suwon-si (KR); Yun A LEE, Suwon-si (KR); Chan Mi LEE, Suwon-si (KR); Sang Gyo CHUNG, Suwon-si (KR); Yun Jong JANG, Seoul (KR); Hae In KWON, Suwon-si (KR); Hong Seong GIL, Suwon-si (KR); Doo San KIM, Suwon-si (KR)

(73) Assignees: Samsung Electronics Co., Ltd., Suwon-si (KR); RESEARCH AND BUSINESS FOUNDATION SUNGKYUNKWAN UNIVERSITY, Suwon-si (KR)

(21) Appl. No.: 18/587,026

(22) Filed: Feb. 26, 2024

(30) Foreign Application Priority Data
Aug. 2, 2023 (KR) 10-2023-0100947
Sep. 27, 2023 (KR) 10-2023-0130746

(51) Int. Cl. H01L 21/67; H01J 37/32; H01L 21/3065

(52) U.S. Cl. CPC H01L 21/67069; H01J 37/32357; H01J 37/32422; H01L 21/3065; H01J 2237/3345

(57) ABSTRACT

An ion beam etching apparatus comprising a plasma chamber, a plasma source disposed on top of the plasma chamber and configured to generate plasma, a process chamber defining a treating area where a substrate is treated, a grid structure disposed between the process chamber and the plasma chamber, wherein the grid structure receives the plasma, and supplies ions or radicals toward the substrate, a discharge line connected to the grid structure, and a first pumping system connected to the discharge line, wherein particles or polymers within the grid structure are discharged through the discharge line.

### CROSS-REFERENCE TO RELATED APPLICATION

This application claims priority from Korean Patent Application No. 10-2023-0100947 filed on Aug. 2, 2023, and No. 10-2023-0130746 filed on Sep. 27, 2023 in the Korean Intellectual Property Office, and all the benefits accruing therefrom under 35 U.S.C. 119, the contents of which in their entirety are herein incorporated by reference.

### BACKGROUND

### Field

The present disclosure relates to an ion beam etching apparatus, a method for manufacturing a semiconductor device using the same, and a substrate treating method using the same.

### Description of Related Art

With the miniaturization and high integration of a semiconductor device, dry etching using plasma is widely used as a pattern etching scheme for finely patterning a semiconductor circuit. Plasma etching is a scheme of generating plasma and reacting ions and radicals contained therein with a target material to etch an etching target. In this regard, the ions have downward directionality and mainly contribute to anisotropic etching of the etching target material, while the radicals are neutral particles and thus have no directionality, but are highly reactive and mainly contribute to isotropic etching of the etching target material.

Among the dry etching schemes using the plasma, reactive ion beam etching is a scheme of extracting and accelerating only the ions from the plasma containing the ions and the radicals to etch the target etching material, and performs precise processing efficiently. In this regard, a voltage is applied to a grid to extract only the ions. However, when foreign substances accumulate on the grid, defects may occur in the grid. Therefore, research to prevent the grid defects and improve etching performance is increasing.

### SUMMARY

The technical purpose that the present disclosure seeks to achieve is to provide an ion beam etching apparatus with improved performance.

Another technical purpose that the present disclosure seeks to achieve is to provide a method for manufacturing a semiconductor device with improved reliability.

Still another technical purpose that the present disclosure seeks to achieve is to provide a substrate treatment method with improved reliability.

Purposes according to the present disclosure are not limited to the above-mentioned purpose. Other purposes and advantages according to the present disclosure that are not mentioned may be understood based on the following descriptions, and may be more clearly understood based on embodiments according to the present disclosure. Further, it will be easily understood that the purposes and advantages according to the present disclosure may be realized using means shown in the claims and combinations thereof.

According to an aspect of the present disclosure, there is provided an ion beam etching apparatus comprising, a plasma chamber, a plasma source disposed on top of the plasma chamber and configured to generate plasma, a process chamber defining a treating area where a substrate is treated, a grid structure disposed between the process chamber and the plasma chamber, wherein the grid structure receives the plasma, and supplies ions or radicals toward the substrate, a discharge line connected to the grid structure, and a first pumping system connected to the discharge line, wherein particles or polymers within the grid structure are discharged through the discharge line.

According to another aspect of the present disclosure, there is provided an ion beam etching apparatus comprising a plasma chamber, a plasma source disposed on top of the plasma chamber and configured to generate plasma, a shower head installed inside the plasma chamber and constructed to receive and supply the plasma, a process chamber defining a treating area where a substrate is treated, a grid structure disposed between the process chamber and the plasma chamber, wherein the grid structure receives the plasma, and are configured to supply ions or radicals to the process chamber under a potential difference thereof, a discharge line connected to the grid structure, wherein particles or polymers within the grid structure are discharged through the discharge line, a discharge pipe connected to the process chamber, wherein the ions or radicals in the process chamber are discharged through the discharge pipe, and a pumping system connected to the discharge line and the discharge pipe including a turbo molecular vacuum pump, wherein the grid structure includes a first grid, a second grid, and a third grid between the first grid and the second grid, wherein the second grid is positioned closer to the substrate than the first grid, and wherein a ground voltage is applied to the second grid, a positive voltage is applied to the first grid, and a negative voltage is applied to the third grid.

According to an aspect of the present disclosure, there is provided a method for manufacturing a semiconductor device, the method comprising loading a substrate into an ion beam etching apparatus, and performing an ion beam etching process on the substrate, wherein the ion beam etching apparatus includes a plasma chamber, a plasma source disposed on top of the plasma chamber and configured to generate plasma, a process chamber defining a treating area where a substrate is treated, a grid structure disposed between the process chamber and the plasma chamber, wherein the grid structure receives the plasma, and supplies ions or radicals toward the substrate, a discharge line connected to the grid structure, wherein particles or polymers within the grid structure are discharged through the discharge line, and a pumping system connected to the discharge line.

According to an aspect of the present disclosure, there is provided a method for treating a substrate, the method comprising providing an ion beam etching apparatus, wherein the ion beam etching apparatus includes a process chamber, a plasma chamber, and a grid structure disposed between the process chamber and the plasma chamber, loading the substrate into the process chamber, supplying plasma to the plasma chamber, applying voltage to the grid structure to supply ions to the process chamber, etching the substrate using the ions, and discharging particles within the grid structure through a discharge line connected to the grid structure.

Specific details of other embodiments are included in detailed descriptions and drawings.

### BRIEF DESCRIPTION OF DRAWINGS

The above and other aspects and features of the present disclosure will become more apparent by describing in detail illustrative embodiments thereof with reference to the attached drawings, in which:

FIG. 1 is a conceptual diagram for illustrating a substrate treating system according to some embodiments of the present disclosure.

FIG. 2 is a plan view for illustrating an ion beam etching apparatus according to some embodiments of the present disclosure.

FIG. 3 is a cross-sectional view as cut along a line A-A in FIG. 2.

FIG. 4 is an enlarged view of a P area in FIG. 3.

FIG. 5 and FIG. 6 are diagrams for illustrating an ion beam etching apparatus according to some further embodiments of the present disclosure.

FIG. 7 is a diagram for illustrating an ion beam etching apparatus according to some still further embodiments of the present disclosure.

FIG. 8 and FIG. 9 are diagrams for illustrating an ion beam etching apparatus according to some still further embodiments of the present disclosure.

FIGS. 10 to 15 are diagrams for illustrating an ion beam etching apparatus according to some still further embodiments of the present disclosure.

FIG. 16 is a flowchart for illustrating a substrate treating method using an ion beam etching apparatus according to some embodiments of the present disclosure.

FIGS. 17 to 20 are diagrams for illustrating a substrate treating method using an ion beam etching apparatus according to some embodiments.

### DETAILED DESCRIPTIONS

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included in the spirit and scope of the present disclosure as defined by the appended claims.

A shape, a size, a ratio, an angle, a number, etc. disclosed in the drawings for illustrating embodiments of the present disclosure are exemplary, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may contact the latter or still another layer, film, region, plate, or the like may be disposed between the former and the latter. As used herein, when a layer, film, region, plate, or the like is directly disposed “on” or “on a top” of another layer, film, region, plate, or the like, the former contacts the latter and still another layer, film, region, plate, or the like is not disposed between the former and the latter. Further, as used herein, when a layer, film, region, plate, or the like is disposed “below” or “under” another layer, film, region, plate, or the like, the former may contact the latter or still another layer, film, region, plate, or the like may be disposed between the former and the latter. As used herein, when a layer, film, region, plate, or the like is directly disposed “below” or “under” another layer, film, region, plate, or the like, the former contacts the latter and still another layer, film, region, plate, or the like is not disposed between the former and the latter.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain embodiment may be implemented differently, a function or operation specified in a specific block may occur in a sequence different from that specified in a flowchart. For example, two consecutive blocks may actually be executed at the same time. Depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated.

The features of the various embodiments of the present disclosure may be partially or entirely combined with each other, and may be technically associated with each other or operate with each other. The embodiments may be implemented independently of each other and may be implemented together in an association relationship.

Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings is turned over, elements described as “below” or “beneath” or “under” other elements or features would then be oriented “above” the other elements or features. Thus, the example terms “below” and “under” may encompass both an orientation of above and below. The device may be otherwise oriented for example, rotated 90 degrees or at other orientations, and the spatially relative descriptors used herein should be interpreted accordingly.

Hereinafter, embodiments according to the technical idea of the present disclosure will be described with reference to the attached drawings.

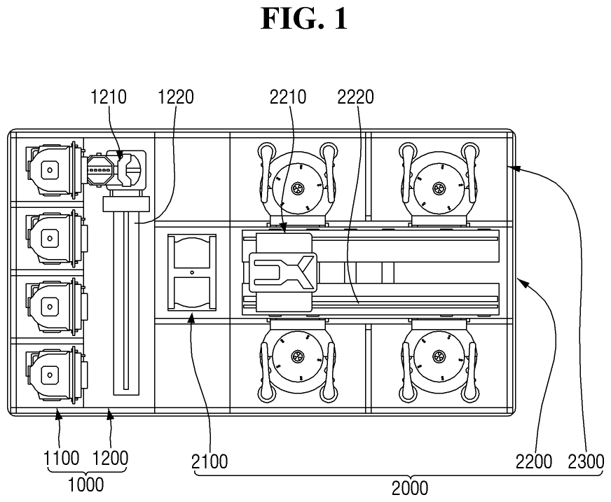

Hereinafter, a substrate treatment system according to some embodiments is described with reference to FIG. 1. FIG. 1 is a conceptual diagram for illustrating a substrate treating system according to some embodiments of the present disclosure.

Referring to FIG. 1, the substrate treating system according to some embodiments may include an index module 1000 and a process module 2000.

The index module 1000 receives a substrate from an outside and transfers the substrate to the process module 2000. The process module 2000 may perform at least one of a cleaning process, a deposition process, an etching process, and an ashing process. The index module 1000 may be embodied as an equipment front end module (EFEM). The index module 1000 may include a load port 1100 and a transfer frame 1200.

The load port 1100 may accommodate therein a substrate. The substrate may be disposed in a container within the load port 1100. The container may be embodied as a front opening unified pod (FOUP). The container may be brought into the load port 1100 from the outside by an overhead transfer (OHT). The container may be taken out from the load port 1100 by the overhead transfer. The transfer frame 1200 may transfer the substrate between the container disposed in the load port 1100 and the process module 2000.

The process module 2000 may be a module that actually performs a process. The process module 2000 may include a buffer chamber 2100, a transfer chamber 2200, and an etching chamber 2300. In some embodiments, the etching chamber 2300 may be embodied as a tower form including a plurality of chambers. However, the present disclosure is not limited thereto.

The buffer chamber 2100 provides a space where the substrate transferred to between the index module 1000 and the process module 2000 temporarily resides. The buffer chamber 2100 may provide a buffer slot in which the substrate is placed. The transfer robot 2210 of the transfer chamber 2200 may withdraw the substrate disposed in the buffer slot and transfer the same to the etching chamber 2300. The buffer chamber 2100 may provide a plurality of buffer slots.

The transfer chamber 2200 transfers the substrate between the buffer chamber 2100 and the etching chamber 2300 disposed therearound. The transfer chamber 2200 may include the transfer robot 2210 and a transfer rail 2220. The transfer robot 2210 may move along the transfer rail 2220 and may transfer the substrate.

In some embodiments, the etching chamber 2300 may be an ion beam etching apparatus. For example, an etching process may be performed within the etching chamber 2300. More specifically, within the etching chamber 2300, an etching process using plasma containing the ions, and/or radicals may be performed. However, the present disclosure is not limited thereto. Furthermore, a cleaning process, a deposition process, and an ashing process may be performed within the etching chamber 2300. Herein, an example is described in which the etching process using an ion beam is performed within the etching chamber 2300.

Some of the etching chambers 2300 may be disposed on one side of the transfer chamber 2200. Other etching chambers 2300 may be disposed on the other side of the transfer chamber 2200. For example, a plurality of etching chambers 2300 may be arranged to face each other while being disposed on both opposing sides of the transfer chamber 2200.

The process module 2000 may be provided with the plurality of etching chambers 2300. The plurality of etching chambers 2300 may be arranged in a row while being disposed on one side of the transfer chamber 2200. However, the technical idea of the present disclosure is not limited thereto.

The arrangement of the etching chamber 2300 is not limited to the above example, and may be changed considering, for example, the facility's footprint or process efficiency.

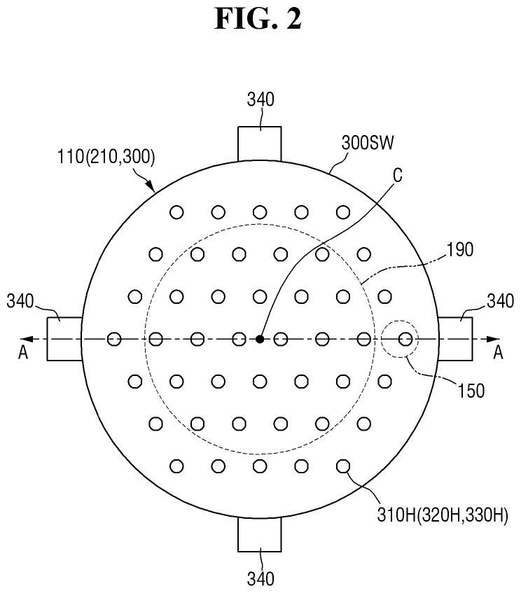

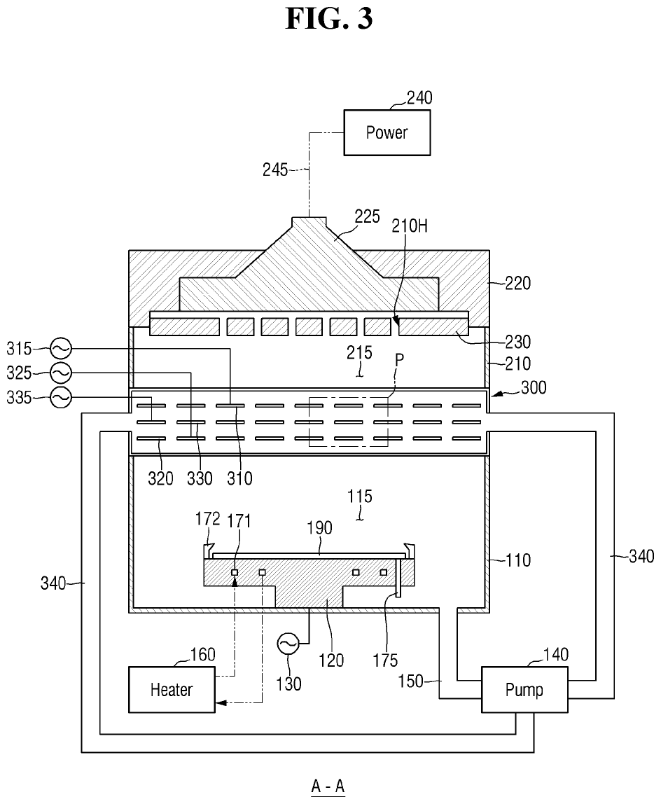

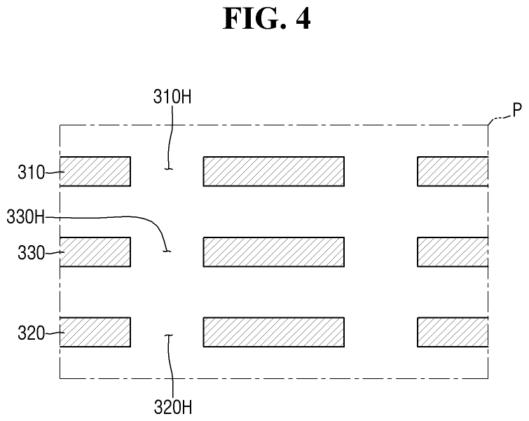

Hereinafter, with reference to FIGS. 2 to 4, an ion beam etching apparatus according to some embodiments of the present disclosure is described in more detail. FIG. 2 is a plan view for illustrating an ion beam etching apparatus according to some embodiments of the present disclosure. FIG. 3 is a cross-sectional view as cut along a line A-A in FIG. 2. FIG. 4 is an enlarged view of the indicated P area in FIG. 3.

Referring to FIGS. 2 to 4, the ion beam etching apparatus according to some embodiments may include a process chamber 110, a plasma chamber 210, and a grid structure 300.

The ion beam etching apparatus according to some embodiments may be a chamber for treating a substrate 190 using ions and/or radicals. For example, within the substrate treating facility, an ion beam etching process may be performed on the substrate 190. However, the technical idea of the present disclosure is not limited thereto. Depending on embodiments, a deposition process, an etching process, and a cleaning process may be performed together within the ion beam etching apparatus.

As used herein, “substrate” may mean the substrate itself, or a stack structure including the substrate and a predetermined layer or film formed on a surface thereof. Furthermore, “the surface of the substrate” may mean an exposed surface of the substrate itself, or an exposed surface of a predefined layer or film formed on the substrate.

For example, the substrate may be a wafer, or may include a wafer and at least one material film on the wafer. The material film may be an insulating film and/or a conductive film formed on the wafer via various schemes such as deposition, coating and plating. For example, the insulating film may include an oxide film, a nitride film, or an oxynitride film, etc. The conductive film may include a metal film or a polysilicon film. In one example, the material film may be a single film formed on a wafer or may be a stack of multi-films formed on a wafer. Furthermore, the material film may have a predetermined pattern and may be formed on the wafer.

The process chamber 110 may define a treating area 115. More specifically, the process chamber 110 and a lower surface of the grid structure 300 may define the treating area 115. The treating area 115 is an area where the substrate 190 is treated. The treating area 115 is an area where an ion beam etching process is performed on the substrate 190. The treating area 115 may be sealed from an outside. A general appearance of the process chamber 110 may have a shape of a cylinder, an elliptical column, or a polygonal column. The process chamber 110 may be generally made of a metal material, and an electrical ground state thereof may be maintained to block noise from the outside during the ion beam etching process.

Although not shown, a liner may be provided along and on an inner wall of the process chamber 110. The liner may protect the process chamber 110 and may cover metal structures within the process chamber 110 to prevent metal contamination due to internal arcing. In one example, the liner may be made of a metal material such as aluminum or a ceramic material. Furthermore, the liner may be formed as a material film resistant to plasma. In this regard, the material film that is resistant to plasma may be, for example, an yttrium oxide (Y₂O₃) film. In another example, the material film resistant to plasma is not limited to the yttrium oxide film.

The process chamber 110 may be connected to a pumping system 140 via a discharge pipe 150. By-products after the ion beam etching process may be discharged via the discharge pipe 150 using the pumping system 140. The by-products may be the ions or radicals remaining inside the process chamber 110 after the ion beam etching process. Furthermore, the pumping system 140 may perform a function of regulating a pressure inside the process chamber 110.

In some embodiments, the pumping system 140 may include a turbomolecular vacuum pump (TMP) having a pumping speed of up to 5000 liters/see (or higher). The turbomolecular vacuum pump may be used at low pressure typically lower than 50 mTorr. At high pressure (i.e., greater than 100 mTorr), a mechanical booster pump and a dry roughing pump may be used.

Although not shown, a pressure measuring device that monitors a pressure of the process chamber 110 may be installed in the process chamber 110. The pressure measurement device may measure the pressure inside the process chamber 110. The pumping speed of the pumping system 140 may be adjusted based on a measuring result of the pressure inside the process chamber 110. Furthermore, a discharge rate at which the by-products (e.g., ions or radicals) are discharged through the discharge pipe 150 may be adjusted based on the measuring result of the pressure inside the process chamber 110.

The plasma chamber 210 may be disposed on top of the process chamber 110. The plasma chamber 210 may define a plasma receiving area 215. The plasma receiving area 215 may be defined by the plasma chamber 210 and a shower head 230, which will be described later.

In some embodiments, a lid 220, an adapter 225, the shower head 230, and a plasma source 240 may be disposed on and at a top of the plasma chamber 210.

The shower head 230 may be disposed within the plasma chamber 210. The shower head 230 may include a plurality of plasma holes 210H through which the plasma may flow. The plasma supplied from a plasma source out of the plasma chamber 210 may be evenly distributed to the plasma receiving area 215 through the plasma hole 210H of the shower head 230.

In some embodiments, the plasma may include halogen elements such as chlorine (Cl), bromine (Br), and fluorine (F). In another example, the plasma may include a carbon-based gas.

The plasma source 240 may be installed outside the plasma chamber 210. The plasma source 240 may generate plasma containing ions and/or radicals and supply the plasma containing ions and/or radicals to the plasma receiving area 215.

For example, the plasma source 240 may supply the plasma containing ions and/or the radicals to the plasma receiving area 215 via a plasma supply line 245. The plasma containing ions and/or radicals are supplied to the plasma receiving area 215 via the adapter 225 and the shower head 230, which will be described later.

The plasma source 240 may apply the power to gas to generate the plasma containing ions and/or radicals. The power may be applied, for example, as radio frequency (RF) power in a form of an electromagnetic wave having a predetermined frequency and a predetermined intensity. Alternatively, the power may be applied in a form of a continuous wave or in a form of a pulse having an on-off cycle in a form of electromagnetic wave.

For reference, the plasma may contain various components such as radicals, ions, electrons, and ultraviolet rays. At least one of the components such as radicals, ions, electrons, and ultraviolet rays may be used to treat the substrate 190, for example, etch the substrate 190. Basically, the radicals are electrically neutral and the ions are electrically polar. Accordingly, the radicals may be used to isotropically remove the etching target in an etching process using the plasma. Furthermore, the ions may be used to anisotropically remove the etching target in an etching process using the plasma.

The adapter 225 may be disposed between the plasma source 240 and the shower head 230. The adapter 225 may act as a passage through which the plasma and/or radicals supplied from the plasma source 240 flow. The plasma and/or the radicals generated from the plasma source 240 flow through the adapter 225 and are provided to the shower head 230. The adapter 225 has a tapered cross-sectional structure in which a width is the largest at a bottom thereof, and a width gradually decreases as the adapter extends from the bottom to a top. For example, the adapter 225 has a structure in which a width of a portion facing the plasma source 240 is the smallest, and a width of a portion facing the shower head 230 is the largest.

The adapter 225 may be vertically spaced from the shower head 230. The vertical direction may be perpendicular to an upper surface of the substrate 190. An empty space may be defined between the adapter 225 and the shower head 230. For example, the adapter 225 does not contact the shower head 230.

The lid 220 may be disposed on top of the plasma chamber 210. The lid 220 may surround at least a portion of the adapter 225. The lid 220 may surround a portion of a sidewall of the shower head 230. The adapter 225 may protrude in the vertical direction beyond an upper surface of the lid 220. However, the present disclosure is not limited thereto. The lid 220 may be made of a metal material such as aluminum (Al). However, the present disclosure is not limited thereto.

The lid 220 may be generally made of a metal material, and may be maintained in an electrical ground state to block noise from the outside during the plasma process. Although not shown, a liner may be disposed on an inner wall of the lid 220. The liner protects the lid 220 and covers metal structures within the lid 220 to prevent metal contamination due to internal arcing. In one example, the liner may be made of a metal material such as aluminum or a ceramic material. Furthermore, the liner may be embodied as a material film resistant to plasma. In this regard, the material film that is resistant to plasma may be, for example, an yttrium oxide (Y₂O₃) film. In another example, the material film resistant to plasma is not limited to the yttrium oxide film.

In some embodiments, a substrate support unit 120 may be installed inside the process chamber 110. The substrate support unit 120 may be disposed under the treating area 115 in the process chamber 110. The substrate support unit 120 may support the substrate 190 thereon.

The substrate support unit 120 may include an electrostatic chuck configured to support the substrate 190 thereon using an electro-static force, and a chuck support supporting the electrostatic chuck thereon.

The electrostatic chuck may include an electrode built therein for chucking and de-chucking the substrate 190. The chuck support supports the electrostatic chuck thereon, and may be made of a metal such as aluminum or a ceramic insulator such as alumina. A heating member such as a heater may be disposed inside the chuck support, and heat from the heater may be transferred to the electrostatic chuck or the substrate 190. Furthermore, a power application wire connected to the electrode of the electrostatic chuck may be disposed in the chuck support. In another example, a configuration of the substrate support unit 120 is not limited thereto, and the substrate support unit 120 may include a vacuum chuck configured to support the substrate 190 thereon using a vacuum, or may be configured to mechanically support the substrate 190.

The substrate support unit 120 may include a lift pin 175. The lift pin 175 may be configured to lift the substrate 190 from a surface of the substrate support unit 120 on which the substrate 190 is seated.

The lift pin 175 may be accommodated in a hole defined in the substrate support unit 120. The lift pin 175 may be installed to be movable in a vertical direction with respect to the substrate support unit 120. The lift pin 175 may move in the vertical direction to raise and lower the substrate 190. The substrate support unit 120 may include a suitable number of lift pins 175 to support the substrate 190 thereon. For example, the substrate support unit 120 may include three or more lift pins 175 arranged so as to be evenly spaced from each other along a circumferential direction of the substrate support unit 170. However, the present disclosure is not limited thereto.

When the substrate 190 as a treating target is brought into the process chamber 110 or the substrate 190 is taken out from the process chamber 110, the lift pin 175 may be in a pin-up state in which the lift pin protrudes upwardly from the substrate support unit 120 so as to support the substrate 190 thereon. Furthermore, while the substrate 190 is being treated in the process chamber 110, the lift pin 175 may be in a pin-down state in which the lift pin is lowered down to a vertical level lower than that of an upper surface of the substrate support unit 120, such that the substrate 190 may be seated on the substrate support unit 120.

An RF bias source 130 may be connected to the substrate support unit 120. The RF bias source 130 may apply RF power to the substrate support unit 120. In some embodiments, the RF bias source 130 may apply low frequency RF power of about 200 kHz or lower to the substrate support unit 120 while the etching process on the substrate 190 is in progress. In some embodiments, the RF bias source 130 may remove the RF power supplied to the substrate support unit 120 while the etching process on the substrate 190 is in progress.

In some embodiments, the substrate support unit 120 may further include a heating member 171 and a rim 172.

The heating member 171 may be connected to the heater 160. The heater 160 may heat the substrate support unit 120. The heater 160 may supply heat to the heating member 171 of the substrate support unit 120. The heater 160 may control a temperature of the substrate support unit 120 and a temperature of the substrate 190 mounted on the substrate support unit 120 by controlling an amount of heat supplied via the heating member 171.

The rim 172 may be provided on the substrate support unit 120. The rim 172 may surround the substrate 190 disposed on the substrate support unit 120. The rim 172 may prevent the substrate 190 from slipping on and along the substrate support unit 120. The rim 172 may include a ceramic material. Because the rim 172 includes the ceramic material, the rim may be vulnerable to reactive stress.

In some embodiments, the grid structure 300 may be interposed between the process chamber 110 and the plasma chamber 210. The grid structure 300 may provide the ions and/or radicals inside the plasma chamber 210 to the process chamber 110. For example, the ions may be provided to the process chamber 110 by applying a voltage to the grid structure 300. The ions may be supplied to the process chamber 110 under a potential difference of the voltage applied to the grid structure 300. An etching process may be performed on the substrate 190 in the process chamber 110 using the ions. The ions may have flow directionality and be supplied to the process chamber 110. Therefore, the etching process using the ions may be an anisotropic etching process. However, the technical idea of the present disclosure is not limited thereto.

In FIG. 3 and FIG. 4, the grid structure 300 may include a first grid 310, a second grid 320, and a third grid 330. However, the technical idea of the present disclosure is not limited thereto. The grid structure 300 may include two or more grids. The number of grids may be changed.

The first grid 310, the second grid 320, and the third grid 330 may be spaced apart from each other in the vertical direction. For example, the first grid 310 may be disposed farther from the substrate 190 than the second grid 320 may be. In other words, a vertical distance from an upper surface of the substrate 190 to the first grid 310 may be greater than a vertical distance from the upper surface of the substrate 190 to the second grid 320. The third grid 330 may be disposed between the first grid 310 and the second grid 320.

In some embodiments, a bias may be applied to each of the first to third grids 310, 320, and 330. When the bias is applied to each of the first to third grids 310, 320, and 330, the ions may be extracted from the plasma of the plasma chamber 210 to generate an ion beam. For example, when the bias is applied to each of the first to third grids 310, 320, and 330, the ion beam may be provided to the process chamber 110. An etching process may be performed on the substrate 190 using the ion beam.

For example, the first grid 310 may include a first grid hole 310H. The second grid 320 may include a second grid hole 320H. The third grid 330 may include a third grid hole 330H. The ions may be supplied to the process chamber 110 through the first grid hole 310H, the second grid hole 320H, and the third grid hole 330H.

In some embodiments, a first power source 315 may be connected to the first grid 310. A second power source 325 may be connected to a second grid 320. A third power source 335 may be connected to the third grid 330.

The first power source 315 may apply a bias to the first grid 310. For example, the first power source 315 may apply a positive voltage to the first grid 310. The second power source 325 may apply a bias to the second grid 320. For example, the second power source 325 may apply a ground voltage to the second grid 320. The third power source 335 may apply a bias to the third grid 330. For example, the third power source 335 may apply a negative voltage to the third grid 330.

In this way, a sign of the voltage applied to the first grid 310 and a sign of the voltage applied to the third grid 330 may be different from each other. In another example, a negative voltage may be applied to the first grid 310 and a positive voltage may be applied to the third grid 330. In this regard, the ground voltage should be applied to the second grid 320.

The ion beam etching apparatus according to some embodiments may further include a discharge line 340 connected to the grid structure 300.

The discharge line 340 may be connected to the grid structure 300. The discharge line 340 may be disposed on a sidewall 300SW of the grid structure 300. At least one discharge line 340 may be disposed. In FIG. 2, it is shown that four discharge lines 340 are arranged on the sidewall 300SW of the grid structure 300, but the technical idea of the present disclosure is not limited thereto.

In some embodiments, the discharge lines 340 may be arranged symmetrically with each other around a center C of the grid structure 300 in a plan view. For example, the discharge lines 340 may be disposed at 12 o'clock, 3 o'clock, 6 o'clock, and 9 o'clock positions, respectively, around the center C of the grid structure 300. However, the present disclosure is not limited thereto. Since the discharge lines 340 are arranged symmetrically with each other around the center C of the grid structure 300, a pressure within the grid structure 300 may be adjusted to be uniform.

The discharge line 340 may act as a passage through which particles or polymers within the grid structure 300 are discharged. The particles may be the plasma provided from the plasma chamber 210, or may be a by-product produced via reaction with the plasma. The polymers may be by-products produced when the plasma includes carbon-based gas.

The discharge line 340 may be connected to the pumping system 140. The pumping system 140 may include a turbomolecular vacuum pump (TMP) as previously described. The pumping speed of the pumping system 140 may be controlled such that a discharge rate at which the particles or the polymers are discharged through the discharge line 340 may be adjusted.

In some embodiments, performance of the grid structure 300 may deteriorate when the particles or polymers accumulate within the grid structure 300. For example, when the particles or polymers accumulate within the grid structure 300, arcing may occur on the first to third grids 310, 320, and 330. When the particles or polymers within the grid structure 300 have been discharged via the discharge line 340, defects on the first to third grids 310, 320, and 330 may be prevented from occurring. Furthermore, when the particles or polymers within the grid structure 300 have been discharged via the discharge line 340, the potential difference of the voltage applied to the first to third grids 310, 320, and 330 may be further increased. Thus, etching performance may be improved when performing the ion beam etching process using the ion beam etching apparatus of the present disclosure.

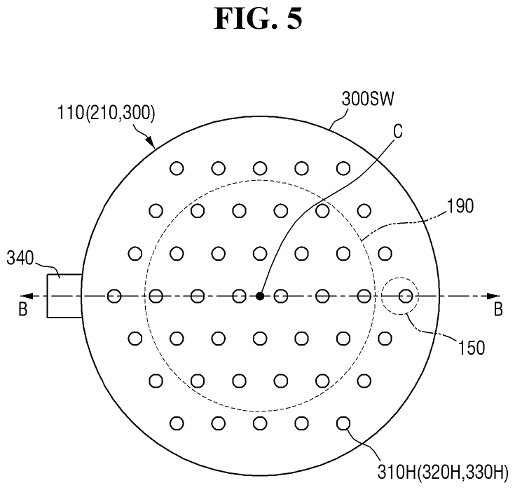

Hereinafter, an ion beam etching apparatus according to some further embodiments of the present disclosure is described with reference to FIGS. 5 to 15. For convenience of description, contents duplicate with what has been described above using FIGS. 2 to 4 is simply described or omitted.

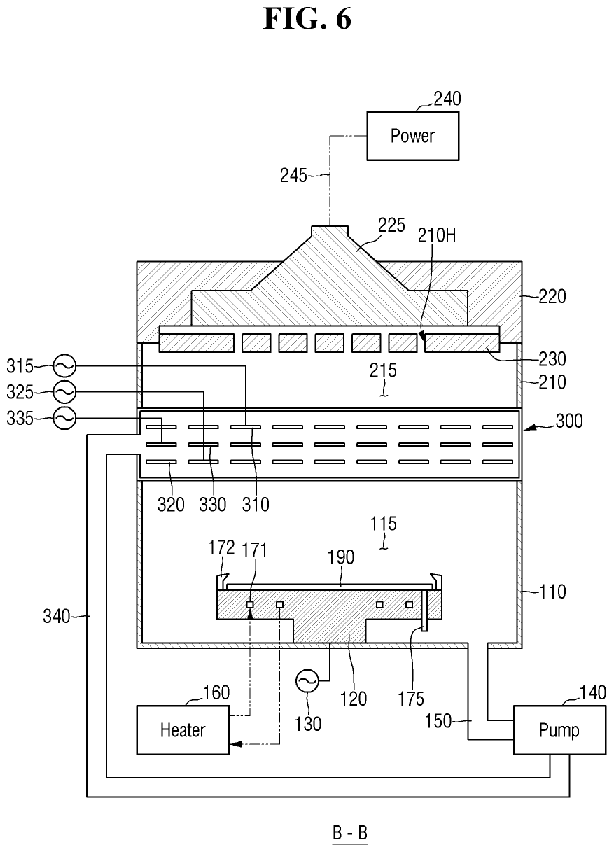

FIG. 5 and FIG. 6 are diagrams for illustrating an ion beam etching apparatus according to some further embodiments of the present disclosure. For reference, FIG. 6 may be a cross-sectional view cut along a line B-B in FIG. 5.

Referring to FIG. 5 and FIG. 6, only one discharge line 340 may be disposed on the sidewall 300SW of the grid structure 300. Furthermore, the discharge line 340 may be arranged asymmetrically around the center C of the grid structure 300.

Specifically, the discharge line 340 may be opposite to the discharge pipe 150 around the center C of the grid structure 300. This arrangement may be intended to adjust the pressure of the process chamber 110.

For example, in FIG. 5, the discharge pipe 150 may be positioned on the right in relation to the center C of the grid structure 300. The discharge pipe 150 may be positioned on the right side around a y-axis passing through the center C of the grid structure 300. In this regard, the pressure inside the process chamber 110 is distributed such that the pressure at a position farther from the discharge pipe 150 is greater than the pressure at a position closer to the discharge pipe 150. For example, the pressure inside the process chamber 110 may not be uniform across the process chamber 110.

Since, as illustrated in FIG. 5, the discharge line 340 is positioned on the left in relation to the center C of the grid structure 300, the pressure at a position inside the process chamber 110 relatively closer to the discharge line 340 may be lowered. In this way, the pressure inside the process chamber 110 may be controlled by adjusting the position of each of the discharge line 340 and the discharge pipe 150. Accordingly, the ion beam etching apparatus with improved reliability may be provided.

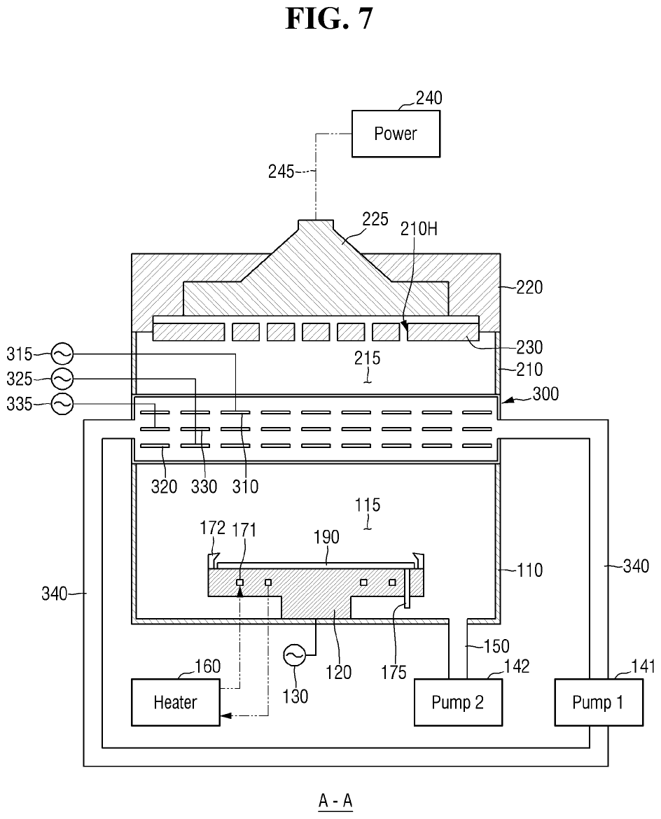

FIG. 7 is a diagram for illustrating an ion beam etching apparatus according to some still further embodiments of the present disclosure.

Referring to FIG. 7, the pumping system may include a first pumping system 141 and a second pumping system 142.

The first pumping system 141 may be connected to at least one discharge line 340. The second pumping system 142 may be connected to the discharge pipe 150. For example, the at least one discharge line 340 and the discharge pipe 150 may be connected to different pumping systems.

Thus, the discharge rate at which the by-products are discharged via the discharge pipe 150 and the discharge rate at which the particles or polymers are discharged via the discharge line 340 may be individually adjusted. Accordingly, the pressure of the process chamber 110 may be adjusted more precisely.

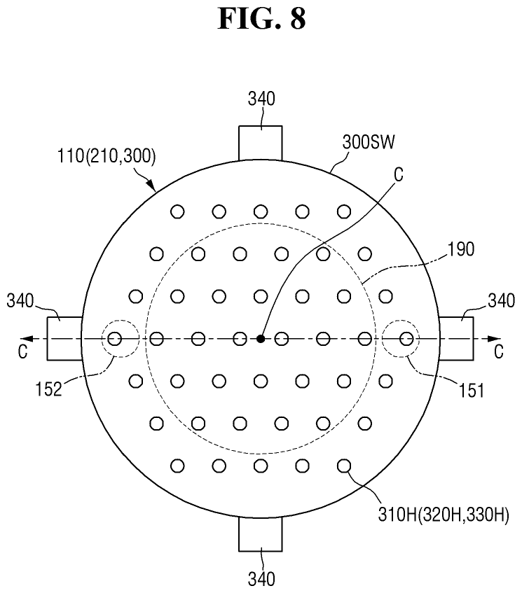

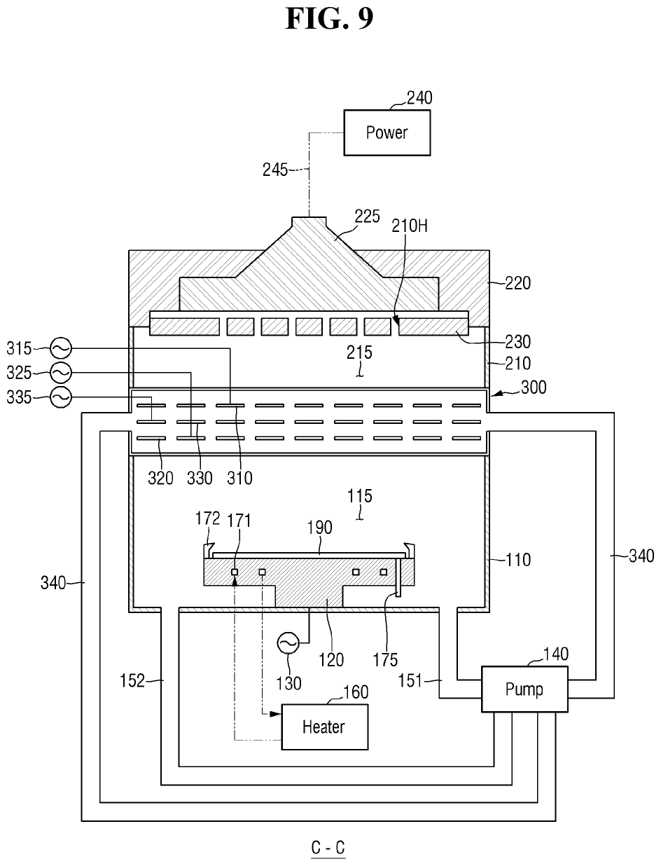

FIG. 8 and FIG. 9 are diagrams for illustrating an ion beam etching apparatus according to some still further embodiments of the present disclosure. For reference, FIG. 9 may be an illustrative cross-sectional view cut along a line C-C in FIG. 8.

Referring to FIG. 8 and FIG. 9, the discharge pipe may include a first discharge pipe 151 and a second discharge pipe 152. As illustrated in FIG. 8, the first discharge pipe 151 may be positioned on the right side in relation to the center C of the grid structure 300. The second discharge pipe 152 may be positioned on the left side in relation to the center C of the grid structure 300.

For example, the first discharge pipe 151 and the second discharge pipe 152 may be arranged symmetrically with each other around the center C of the grid structure 300. Thus, the pressure inside the process chamber 110 may be controlled more uniformly and precisely.

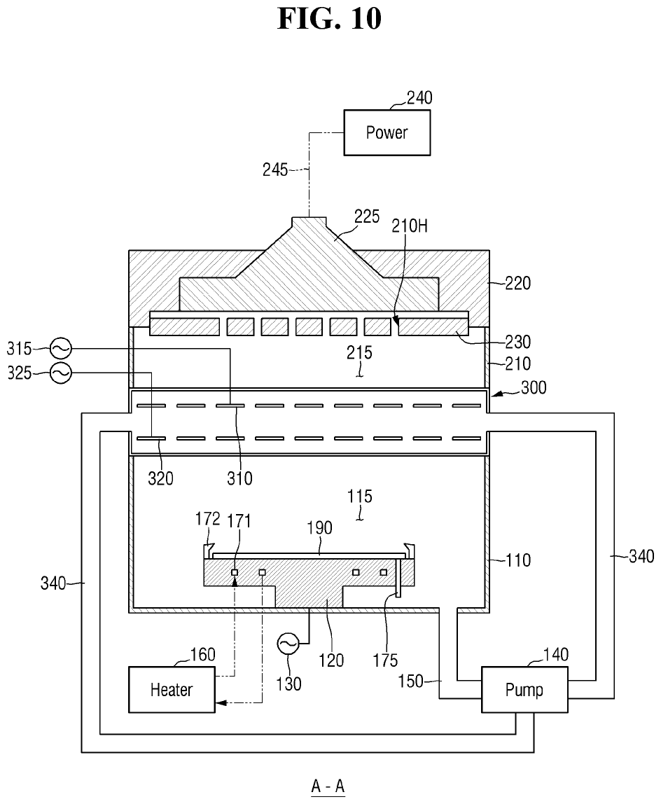

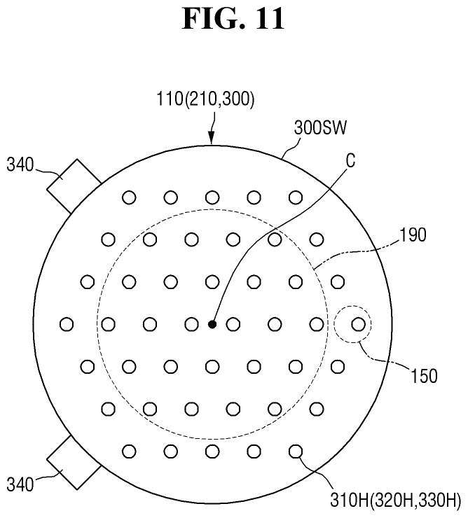

FIGS. 10 to 15 are diagrams for illustrating an ion beam etching apparatus according to some still further embodiments of the present disclosure. For reference, FIG. 10 may be a cross-sectional view for illustrating an ion beam etching apparatus according to some still other embodiments of the present disclosure. FIGS. 11 to 15 may be plan views for illustrating an ion beam etching apparatus according to some still further embodiments of the present disclosure.

First, referring to FIG. 10, the grid structure 300 may include the first grid 310 and the second grid 320. For example, the grid structure 300 may include only two grids.

In some embodiments, the first power source 315 may be connected to the first grid 310. The second power source 325 may be connected to the second grid 320. The first power source 315 may apply a bias to the first grid 310. For example, the first power source 315 may apply a positive voltage to the first grid 310. The second power source 325 may apply a bias to the second grid 320. For example, the second power source 325 may apply a ground voltage to the second grid 320. Alternatively, the first power source 315 may apply a negative voltage to the first grid 310. In this regard, the second power source 325 may apply a ground voltage to the second grid 320.

For example, a positive or negative voltage may be applied to the grid relatively distant from the substrate 190, and a ground voltage may be applied to the grid relatively closer to the substrate 190.

Referring to FIG. 11, the discharge line 340 may be arranged asymmetrically around the center C of the grid structure 300. In this regard, the discharge line 340 may be arranged symmetrically with each other in relation to an x-axis passing through the center C of the grid structure 300. The discharge lines 340 may be positioned on the left in relation to the y-axis passing through the center C of the grid structure 300.

As previously described, the discharge pipe 150 may be positioned on the right side in relation to the y-axis passing through the center C of the grid structure 300. This arrangement may be intended to more easily control the pressure inside the process chamber 110.

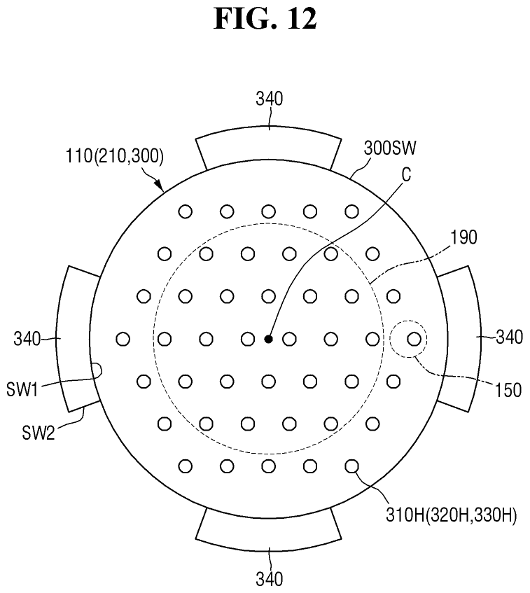

Referring to FIG. 12, a shape of the discharge line 340 may be a slit shape. For example, in a plan view of the apparatus, the discharge line 340 may include a first sidewall SW1 and a second sidewall SW2. The first sidewall SW1 may contact the sidewall 300SW of the grid structure 300. The second sidewall SW2 may extend in a direction perpendicular to the sidewall 300SW of the grid structure 300.

In some embodiments, a length of the first sidewall SW1 may be greater than a length of the second sidewall SW2. However, the technical idea of the present disclosure is not limited thereto.

The slit-shaped discharge lines 340 may also be arranged symmetrically with each other around the center C of the grid structure 300. For example, around the center C of the grid structure 300, four discharge lines 340 may be positioned at 12 o'clock, 3 o'clock, 6 o'clock, and 9 o'clock positions, respectively. However, the present disclosure is not limited thereto.

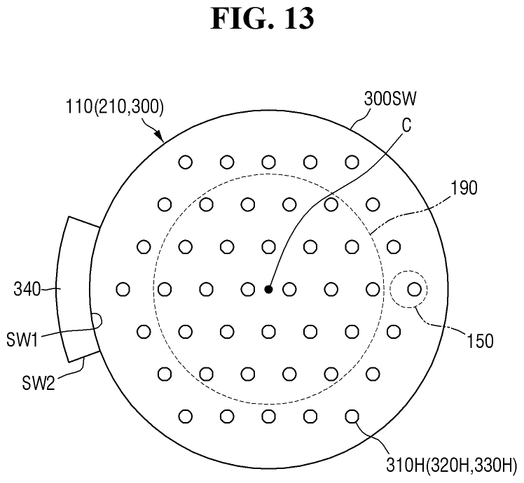

Referring to FIG. 13, the shape of the discharge line 340 may be a slit shape. Only one discharge line 340 may be disposed on the sidewall 300SW of the grid structure 300. In this regard, the discharge line 340 may be arranged asymmetrically around the center C of the grid structure 300.

Specifically, the discharge line 340 may be opposite to the discharge pipe 150 around the center C of the grid structure 300. This arraignment may be intended to adjust the pressure of the process chamber 110 as described previously.

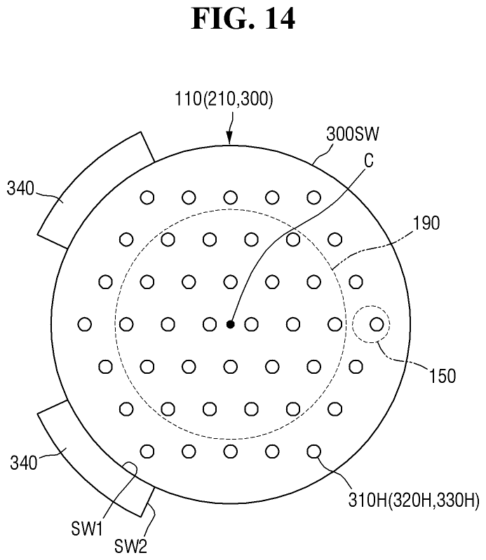

Referring to FIG. 14, the shape of the discharge line 340 may be a slit shape. Two discharge lines 340 may be disposed on the sidewall 300SW of the grid structure 300. In this regard, the discharge lines 340 may be arranged asymmetrically around the center C of the grid structure 300. Specifically, the two discharge lines 340 may be arranged symmetrically with each other in relation to the x-axis passing through the center C of the grid structure 300.

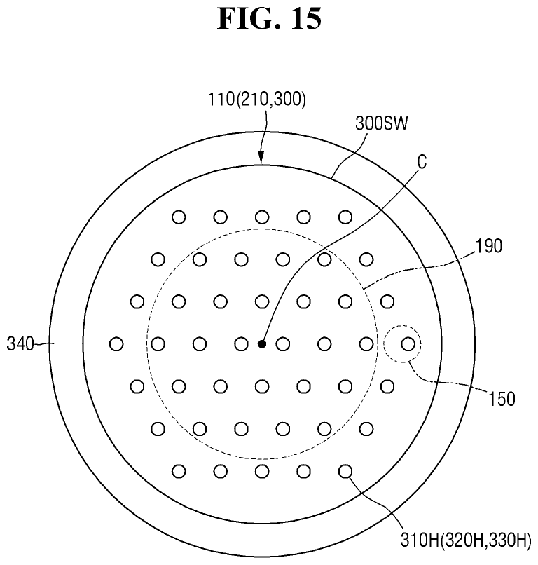

Referring to FIG. 15, the discharge line 340 may entirety surround the sidewall 300SW of the grid structure 300. The particles and/or polymers within the grid structure 300 may be discharged out of the grid structure 300 while not having flow directionality.

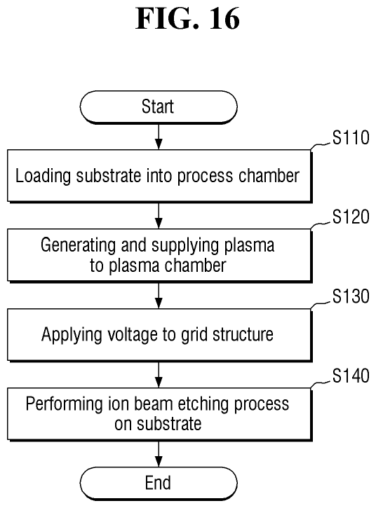

Hereinafter, with reference to FIGS. 16 to 20, a substrate treating method and a method for manufacturing a semiconductor device using an ion beam etching apparatus according to some embodiments of the present disclosure are described.

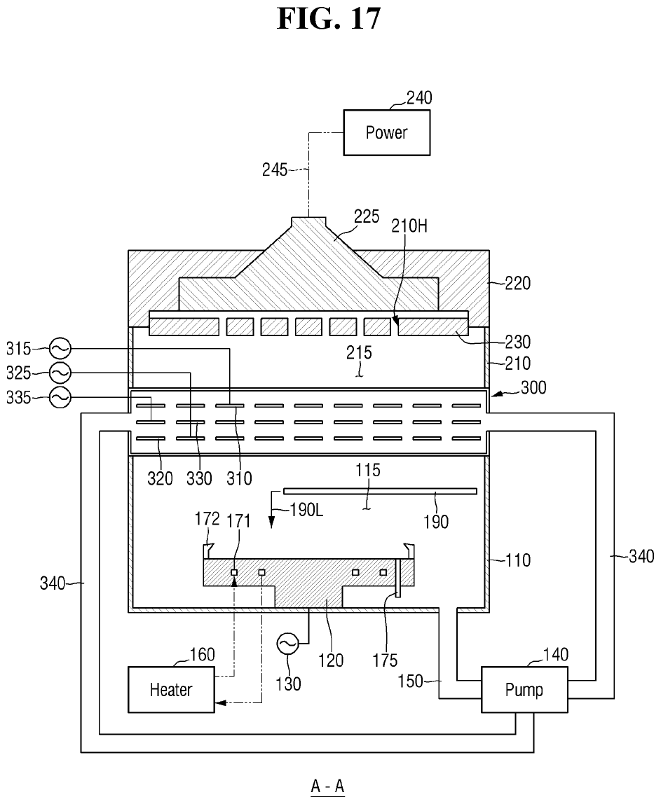

FIG. 16 is a flowchart for illustrating a substrate treating method using an ion beam etching apparatus according to some embodiments of the present disclosure. FIGS. 17 to 20 are diagrams for illustrating a substrate treating method using an ion beam etching apparatus according to some embodiments.

Referring to FIG. 16 and FIG. 17, an ion beam etching apparatus may be provided. The ion beam etching apparatus may include the process chamber 110, the plasma chamber 210, and the grid structure 300.

The substrate support unit 120 may be disposed inside the process chamber 110. The shower head 230, the adapter 225, and the lid 220 may be disposed at a top or on top of the plasma chamber 210. Furthermore, the plasma source 240 that generates plasma may be disposed on top of the plasma chamber 210.

Subsequently, the substrate 190 may be loaded into the ion beam etching apparatus in S110. The substrate 190 may be loaded into the process chamber 110 (see a reference numeral 190L). The substrate 190 may be loaded into the process chamber 110 so as to be disposed on the substrate support unit 120. For example, before the substrate 190 is loaded on the substrate support unit 120, the lift pin 175 of the substrate support unit 120 may be in the pin-down state. When the substrate 190 has been placed on the substrate support unit 120, the lift pin 175 may be brought into the pin-up state. Thus, the lift pin 175 may support the substrate 190 thereon.

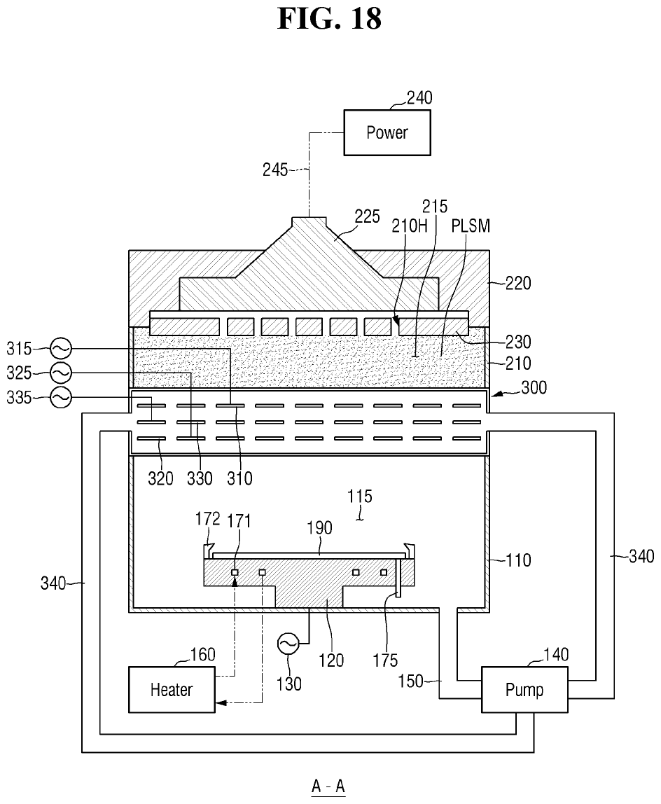

Referring to FIG. 16 and FIG. 18, the plasma may be generated and supplied to the plasma chamber 210 in S120.

First, a bias may be applied to the plasma source 240. The plasma source 240 may apply the power to the gas to generate the plasma containing ions and/or radicals. The power may be applied, for example, as radio frequency (RF) power in a form of an electromagnetic wave having a predetermined frequency and a predetermined intensity. Alternatively, the power may be applied in a form of a continuous wave or in a form of a pulse having an on-off cycle in a form of electromagnetic wave. Hereinafter, an example in which the plasma containing ions is generated by the plasma source 240 will be described.

The plasma source 240 may generate plasma PLSM and supply the plasma PLSM to the plasma receiving area 215. The plasma PLSM is supplied to the plasma receiving area 215 via the plasma supply line 245, the adapter 225 and the shower head 230. The plasma PLSM may fully fill the plasma receiving area 215.

Specifically, the plasma generated from the plasma source 240 flows through the plasma supply line 245, then flows through the adapter 225 and then is provided to the shower head 230. The shower head 230 may include the plurality of plasma holes 210H through which the plasma may flow. The plasma PLSM may be supplied to the plasma receiving area 215 through the plurality of plasma holes 210H.

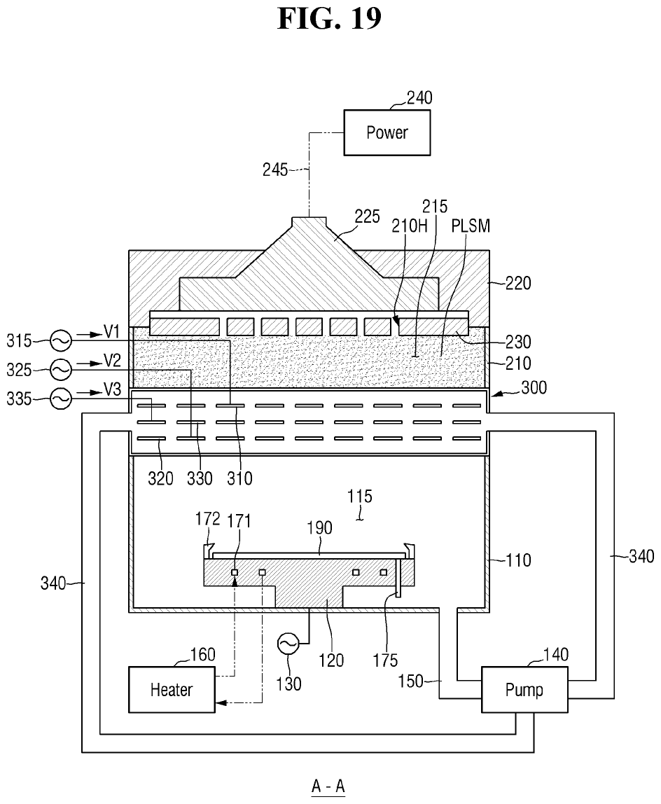

Referring to FIG. 16 and FIG. 19, the voltage may be applied to the grid structure 300 in S130.

Specifically, the voltage may be applied to the first grid 310, the second grid 320, and the third grid 330 within the grid structure 300.

The first power source 315 may be connected to the first grid 310. The second power source 325 may be connected to the second grid 320. The third power source 335 may be connected to the third grid 330.

The first power source 315 may apply a first voltage V1 to the first grid 310. The second power source 325 may apply a second voltage V2 to the second grid 320. The third power source 335 may apply a third voltage V3 to the third grid 330. In this regard, the first voltage V1 may be a positive voltage, the second voltage V2 may be the ground voltage, and the third voltage V3 may be a negative voltage. However, the technical idea of the present disclosure is not limited thereto. In another example, the first voltage V1 may be a negative voltage, and the second voltage V2 may be the ground voltage, and the third voltage V3 may be a positive voltage.

In some embodiments, the ions or radicals may be supplied to the process chamber 110 under the potential difference between the first voltage V1 and the third voltage V3.

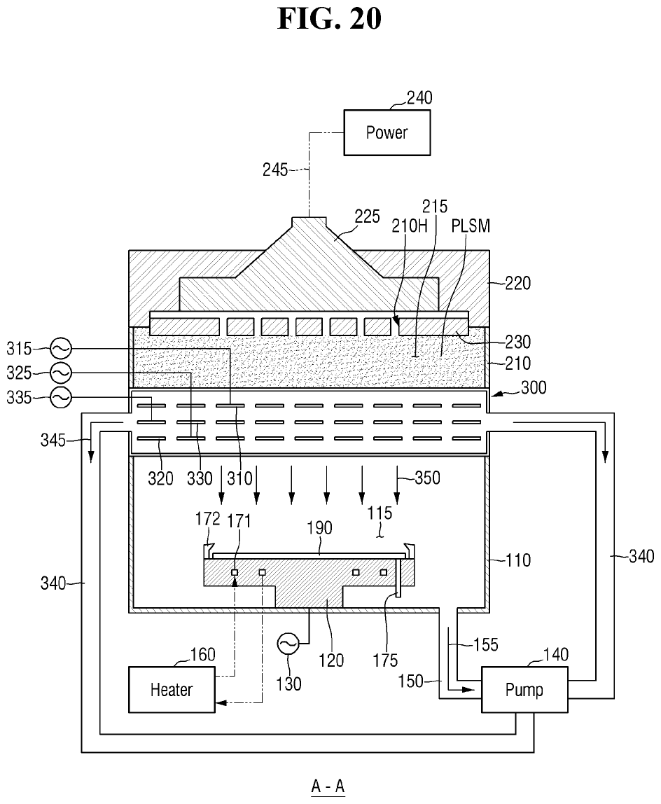

Referring to FIG. 16 and FIG. 20, an ion beam etching process may be performed on the substrate 190 in S140.

First, the ions may be supplied to the process chamber 110 (see a reference numeral 350). The ions may be supplied toward the substrate 190. The ions may have flow directionality and thus may be supplied toward the substrate 190. For example, an anisotropic etching process may be performed on the substrate 190 using the ions.

As previously described, the ions may be provided to the process chamber 110 under the potential difference between the voltages applied to the first to third grids 310, 320, and 330. The larger the potential difference, the better the performance of the etching process.

The pumping system 140 may operate while the ion beam etching process is performed. In this regard, the particles and/or the polymers within the grid structure 300 may be discharged via the discharge line 340. Since the particles and/or the polymers in the grid structure 300 are discharged via the discharge line 340, defects on the first to third grids 310, 320, and 330 may be prevented.

Furthermore, since the particles and/or polymers in the grid structure 300 are discharged via the discharge line 340, the potential difference between the voltages applied to the first to third grids 310, 320, and 330 may be increased. Accordingly, a substrate treatment method with improved performance and reliability may be provided.

By-products inside the process chamber 110 may be discharged via the discharge pipe 150 (see a reference numeral 155). The pressure inside the process chamber 110 may be adjusted by controlling the discharge rate at which the by-products are discharged through the discharge pipe 150. Likewise, the pressure inside the process chamber 110 may be adjusted by controlling the discharge rate at which the particles and/or polymers are discharged via the discharge line 340. Although not illustrated, the pumping system 140 may include one or more discharge ports to further remove the particles and/or the polymers received via the discharge line 340 from the grid structure and the by-products (e.g., ions or radicals) received from the process chamber 110 via the discharge pipe 150 from the ion beam etching apparatus. The one or more discharge ports may also be provided in each of the first pumping system 141 and the second pumping system 142 illustrated in FIG. 7.

A semiconductor device may be manufactured using the ion beam etching apparatus according to some embodiments of the present disclosure.

For example, the substrate 190 may be loaded into the ion beam etching apparatus, and an ion beam etching process may be performed on the substrate 190 using the substrate treating method as described using FIGS. 16 to 20. Thus, the semiconductor device with improved performance and reliability may be manufactured.

Although the embodiments of the present disclosure have been described above with reference to the accompanying drawings, the present disclosure may not be limited to the embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that the embodiments as described above are not restrictive but illustrative in all respects.

1. An ion beam etching apparatus comprising:
a plasma chamber;
a plasma source disposed on top of the plasma chamber and configured to generate plasma;
a process chamber defining a treating area where a substrate is treated;
a grid structure disposed between the process chamber and the plasma chamber, wherein the grid structure receives the plasma, and supplies ions or radicals toward the substrate;
a discharge line connected to the grid structure; and
a first pumping system connected to the discharge line,
wherein particles or polymers within the grid structure are discharged through the discharge line.

2. The ion beam etching apparatus of claim 1, wherein the grid structure includes a first grid and a second grid,
wherein the second grid is positioned closer to the substrate than the first grid, and
wherein a ground voltage is applied to the second grid.

3. The ion beam etching apparatus of claim 2, wherein the grid structure further includes a third grid disposed between the first grid and the second grid, and
wherein a positive voltage is applied to the first grid, and a negative voltage is applied to the third grid.

4. The ion beam etching apparatus of claim 1, further comprising:
a discharge pipe connected to the process chamber, wherein the ions or radicals in the process chamber are discharged through the discharge pipe,
wherein the discharge pipe is connected to the first pumping system.

5. The ion beam etching apparatus of claim 1, further comprising:
a discharge pipe connected to the process chamber, wherein the ions or radicals in the process chamber are discharged through the discharge pipe; and
a second pumping system connected to the discharge pipe.

6. The ion beam etching apparatus of claim 1, wherein the first pumping system includes a turbomolecular vacuum pump.

7. The ion beam etching apparatus of claim 1, further comprising:
a plurality of discharge lines,
wherein in a plan view of the ion beam etching apparatus, the plurality of discharge lines are symmetrically arranged with each other around a center of the grid structure.

8. The ion beam etching apparatus of claim 1, further comprising:
a plurality of discharge lines,
wherein in a plan view of the ion beam etching apparatus, the plurality of discharge lines are asymmetrically arranged with each other around a center of the grid structure.

9. The ion beam etching apparatus of claim 1, wherein in a plan view of the ion beam etching apparatus, the discharge line surrounds an entirety of a sidewall of the grid structure.

10. The ion beam etching apparatus of claim 1, wherein the plasma includes a carbon-based gas.

11. An ion beam etching apparatus comprising:
a plasma chamber;
a plasma source disposed on top of the plasma chamber and configured to generate plasma;
a shower head installed inside the plasma chamber and configured to receive and supply the plasma;
a process chamber defining a treating area where a substrate is treated;
a grid structure disposed between the process chamber and the plasma chamber, wherein the grid structure receives the plasma, and is configured to supply ions or radicals to the process chamber under a potential difference thereof;
a discharge line connected to the grid structure, wherein particles or polymers within the grid structure are discharged through the discharge line;
a discharge pipe connected to the process chamber, wherein the ions or radicals in the process chamber are discharged through the discharge pipe; and
a pumping system connected to the discharge line and the discharge pipe including a turbo molecular vacuum pump,
wherein the grid structure includes a first grid, a second grid, and a third grid between the first grid and the second grid,
wherein the second grid is positioned closer to the substrate than the first grid, and
wherein a ground voltage is applied to the second grid, a positive voltage is applied to the first grid, and a negative voltage is applied to the third grid.

12. The ion beam etching apparatus of claim 11, further comprising:
a plurality of discharge lines,
wherein in a plan view of the ion beam etching apparatus, the plurality of discharge lines are symmetrically arranged with each other around a center of the grid structure.

13. The ion beam etching apparatus of claim 11, further comprising:
a plurality of discharge lines,
wherein in a plan view of the ion beam etching apparatus, the plurality of discharge lines are asymmetrically arranged with each other around a center of the grid structure.

14. The ion beam etching apparatus of claim 11, wherein in a plan view of the ion beam etching apparatus, the discharge line surrounds an entirety of a sidewall of the grid structure.

15. The ion beam etching apparatus of claim 11, wherein each of the first to third grids includes a plurality of holes, and
wherein the ions or the radicals flow through the plurality of holes and then are provided to the process chamber.

16. The ion beam etching apparatus of claim 11, wherein a pressure in the process chamber is controlled to be uniform across the process chamber by adjusting a position of each of the discharge line and the discharge pipe.

17. The ion beam etching apparatus of claim 11, wherein the plasma includes a carbon-based gas.

18. A method for manufacturing a semiconductor device, the method comprising:
loading a substrate into an ion beam etching apparatus; and
performing an ion beam etching process on the substrate,
wherein the ion beam etching apparatus includes:
a plasma chamber;
a plasma source disposed on top of the plasma chamber and configured to generate plasma;
a process chamber defining a treating area where a substrate is treated;
a grid structure disposed between the process chamber and the plasma chamber, wherein the grid structure receives the plasma, and supplies ions or radicals toward the substrate;
a discharge line connected to the grid structure, wherein particles or polymers within the grid structure are discharged through the discharge line; and
a pumping system connected to the discharge line.

19. The method of claim 18, wherein the grid structure includes a first grid and a second grid,
wherein the second grid is positioned closer to the substrate than the first grid, and
wherein a ground voltage is applied to the second grid.

20. The method of claim 18, wherein the ion beam etching apparatus further includes a discharge pipe connected to the process chamber, wherein the ions or radicals in the process chamber are discharged through the discharge pipe, and
wherein the discharge pipe is connected to the pumping system.

21-24. (canceled)
